(19) United States
(12) Patent Application Publication
(10) Pub. No.: US 2025/0234631 A1
(43) Pub. Date: Jul. 17, 2025

(54) SHARED SOURCE/DRAIN CONTACT

(71) Applicant: INTERNATIONAL BUSINESS MACHINES CORPORATION, ARMONK, NY (US)

(72) Inventors: Lijuan Zou, Albany, NY (US); Tao Li, Slingerlands, NY (US); Ruilong Xie, Niskayuna, NY (US); Min Gyu Sung, Latham, NY (US)

(21) Appl. No.: 18/410,068

(22) Filed: Jan. 11, 2024

(51) Int. Cl. H01L 21/8234; H01L 27/088; H01L 29/06; H01L 29/417; H01L 29/423; H01L 29/66; H01L 29/775; H01L 29/786

(52) U.S. Cl. CPC H10D 84/038; H10D 30/014; H10D 30/43; H10D 30/6729; H10D 30/6735; H10D 30/6757; H10D 62/121; H10D 84/013; H10D 84/0149; H10D 84/83

(57) ABSTRACT

Embodiments of present invention provide a semiconductor structure. The semiconductor structure includes a first transistor having a first source/drain (S/D) region; a second transistor having a second S/D region, the second S/D region being on top of the first S/D region; and a shared S/D contact, the shared S/D contact having a first portion being in direct contact with a bottom surface of the second S/D region of the second transistor and a second portion being wrapped around by the first S/D region of the first transistor. A method of forming the same is also provided.

### BACKGROUND

The present application relates to manufacturing of semiconductor integrated circuits. More particularly, it relates to a method of forming shared S/D contact and the structure formed thereby.

As semiconductor industry moves towards smaller node, field-effect-transistors (FETs) are aggressively scaled to fit into the reduced footprint or real estate, which is often dictated by the node size, with increased device density. For example, two transistors may be vertically stacked together to double the density of transistors in a given footprint. In the meantime, backside power rail (BPR) and backside power distribution network (BSPDN) are used to provide signal powering and/or routing functionalities to the stacked transistors.

In an attempt to contact source/drain regions of both the bottom and the top transistor in a stacked transistor structure, it is usually necessary to first form an opening, which has a high-aspect ratio in order to reach the source/drain regions of both the bottom and the top transistors. The opening is then filled with a conductive material to form a contacting via. However, forming high-aspect ratio openings has its own process complexity such as, for example causing complete epi etch-out if not managed properly.

### SUMMARY

Embodiments of present invention provide a semiconductor structure. The semiconductor structure includes a first transistor having a first source/drain (S/D) region; a second transistor having a second S/D region, the second S/D region being on top of the first S/D region; and a shared S/D contact, the shared S/D contact having a first portion being in direct contact with a bottom surface of the second S/D region of the second transistor and a second portion being wrapped around by the first S/D region of the first transistor.

According to one embodiment, the semiconductor structure further includes a backside S/D contact in contact with a bottom surface of the second portion of the shared S/D contact.

In one embodiment, the first portion of the shared S/D contact has a first horizontal cross-section, and the second portion of the shared S/D contact has a second horizontal cross-section; the first horizontal cross-section being larger than the second horizontal cross-section.

In another embodiment, the backside S/D contact has a third horizontal cross-section, the third horizontal cross-section being larger than the second horizontal cross-section.

In one embodiment, the first portion of the shared S/D contact is in direct contact with a top surface of the first S/D region that surrounds the second portion of the shared S/D contact.

In another embodiment, the backside S/D contact is in direct contact with a bottom surface of the first S/D region that surrounds the second portion of the shared S/D contact.

According to one embodiment, the semiconductor structure further includes a backside interconnect structure underneath the first transistor, where the second portion of the shared S/D contact is insulated from the backside interconnect structure by a dielectric capping layer.

According to another embodiment, the semiconductor structure further includes a contact metal directly above and insulated from the second S/D region of the second transistor, the contact metal extending from a frontside S/D contact of a nearby transistor.

Embodiments of present invention also provide a method of forming a semiconductor structure. The method includes forming a raw source/drain (S/D) region of a first transistor on top of a placeholder, the placeholder being formed in a substrate; forming a middle-dielectric-insulator (MDI) layer on top of the raw S/D region; forming a second S/D region of a second transistor on top of, via the MDI layer, the raw S/D region; replacing the substrate with a dielectric layer and removing the placeholder to create a first opening in the dielectric layer, the first opening exposing a bottom surface of the raw S/D region; removing a portion of the raw S/D region to create a first S/D region and a second opening surrounded by the first S/D region, the second opening exposing a bottom surface of the MDI layer; removing the MDI layer exposed by the second opening to create a third opening; and forming a shared S/D contact by filling the third opening with a conductive material to form a first portion of the shared S/D contact and filling the second opening with the conductive material to form a second portion of the shared S/D contact.

In one embodiment, removing a portion of the raw S/D region includes forming a spacer layer at sidewalls of the first opening, the spacer layer being directly on top of a bottom surface of the first S/D region and exposing the portion of the raw S/D region, and removing the portion of the raw S/D region in a selective etch process.

According to one embodiment, the method further includes removing the spacer layer to expose the bottom surface of the first S/D region; and depositing the conductive material in the first opening to form a backside S/D contact, the backside S/D contact in direct contact with a bottom surface of the second portion of the shared S/D contact and with the bottom surface of the first S/D region.

According to another embodiment, the method further includes covering the backside S/D contact with a dielectric capping layer; and forming a backside interconnect structure, the backside interconnect structure being insulated from the shared S/D region by the dielectric capping layer.

In one embodiment, removing the MDI layer includes etching the MDI layer in an isotropic etch process, through the second opening, to expose a bottom surface of the second S/D region and a top surface of the first S/D region.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B to FIGS. 12A and 12B are demonstrative illustrations of cross-sectional views and FIG. 1C to FIG. 12C are simplified top views of a semiconductor structure at various steps of manufacturing thereof according to embodiments of present invention;

FIGS. 13A and 13B are demonstrative illustrations of cross-sectional views and FIG. 13C is a simplified top view of a semiconductor structure according to another embodiment of present invention;

FIGS. 14A and 14B are demonstrative illustrations of cross-sectional views and FIG. 14C is a simplified top view of a semiconductor structure according to yet another embodiment of present invention; and

FIG. 15 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

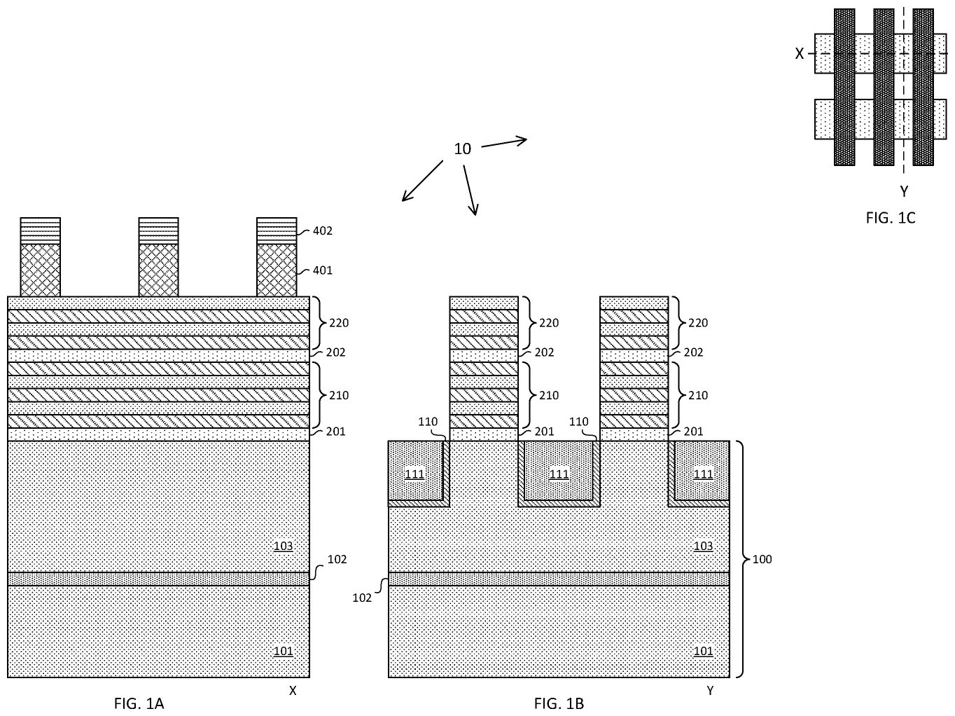

FIGS. 1A and 1B are demonstrative illustrations of different cross-sectional views and FIG. 1C is a simplified top view of a semiconductor structure in a step of manufacturing thereof according to one embodiment of present invention. More specifically, FIG. 1A illustrates a cross-sectional view of the semiconductor structure along a dashed line X as illustrated in FIG. 1C. In other words, the cross-sectional view in FIG. 1A is made across the gate in a direction along the length of the gate. FIG. 1B illustrates a cross-sectional view of the semiconductor structure along a dashed line Y as illustrated in FIG. 1C. In other words, the cross-sectional view in FIG. 1B is made across the S/D region in a direction along the width of the gate. As its purpose is to illustrate locations of the cross-sections illustrated in FIGS. 1A and 1B, FIG. 1C may selectively illustrate only key elements such as, for example, nanosheets, gates, S/D regions that are formed or yet to be formed or whose views may sometimes be obstructed. Other elements such as dielectric cap layer, sidewall spacers, etc. may not necessarily be illustrated in order not to overcrowd FIG. 1C, and to the extent that their omission from FIG. 1C does not hinder the description of embodiments of present invention, which are mainly provided hereinafter with reference to FIGS. 1A and 1B.

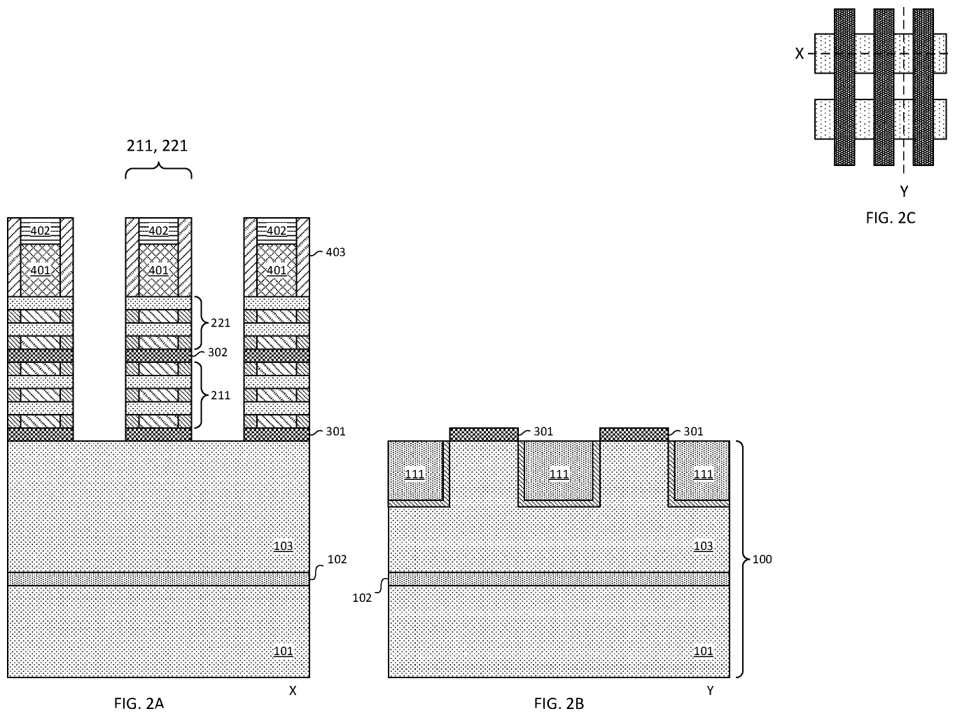

Likewise, FIGS. 2A and 2B to FIGS. 14A and 14B are demonstrative cross-sectional views and FIG. 2C to FIG. 12C are simplified top views of the semiconductor structure, at various manufacturing steps or for different embodiments, illustrated in manners similar to FIGS. 1A, 1B, and 1C respectively.

Embodiments of present invention provide forming a semiconductor structure 10 by first receiving or providing a semiconductor substrate 100. The semiconductor substrate 100 may include a bulk silicon (Si) substrate 101, an etch-stop layer 102 on top of the Si substrate 101, and a Si layer 103 on top of the etch-stop layer 102. In one embodiment, the etch-stop layer 102 may be a layer of silicon-germanium (SiGe) containing a certain percentage of germanium (Ge) such as, for example, 25 at. % and a layer of such composition is generally referred to as a SiGe25 layer. In other words, the etch-stop layer 102 may be a SiGe25 layer. In another embodiment, the semiconductor substrate 100 may be a silicon-on-insulator (SOI) substrate with an insulating layer of, for example, silicon-oxide (SiO₂) or silicon-nitride (SiN) between a bulk substrate 101 and a Si layer 103. This insulating layer may work as an etch-stop layer 102 as well.

Embodiments of present invention further provide proceeding to form a first sacrificial insulation sheet 201 on top of the Si layer 103; a first raw stack of nanosheets 210 on top of the first sacrificial insulation sheet 201; a second sacrificial insulation sheet 202 on top of the first raw stack of nanosheets 210; and a second raw stack of nanosheets 220 on top of the second sacrificial insulation sheet 202.

The first and the second raw stack of nanosheets 210 and 220 may be formed by first forming or depositing a first and a second stack of blanket semiconductor sheets such as, for example, a first and a second stack of alternating blanket silicon (Si) sheets and sacrificial silicon-germanium (SiGe) sheets on top of a first blanket sacrificial insulation sheet. The first and the second stack of blanket semiconductor sheets may be separated by a second blanket sacrificial insulation sheet. This first and second stacks of blanket semiconductor sheets may then be patterned, for example, through a lithographic patterning and etching process to form the first raw stack of nanosheets 210 and the second raw stack of nanosheets 220. In the meantime, the first and the second blanket sacrificial insulation sheet may be patterned to become the first and the second sacrificial insulation sheet 201 and 202 respectively.

After forming the first and the second raw stack of nanosheets 210 and 220, one or more shallow-trench-isolations (STIs) 111 may be formed in the Si layer 103 of the semiconductor substrate 100, in areas not covered by the first and the second raw stack of nanosheets 210 and 220. More specifically, openings or recesses may first be created in the Si layer 103, a dielectric liner 110 such as SiN may then be formed to line the openings or recesses in the Si layer 103. Subsequently, dielectric materials may be used to fill the openings or recesses, for example through a deposition process, to form the one or more STIs 111.

Embodiments of present invention further provide forming one or more dummy gates 401 on top of the first and the second raw stack of nanosheets 210 and 220. For example, a layer of dummy gate material such as, for example, polysilicon or dielectric, may be blanketly deposited to cover the first and the second raw stack of nanosheets 210 and 220. A layer of hard mask material, such as silicon-nitride (SiN), may be formed on top of the dummy gate material and then lithographically patterned to form a hard mask 402. The pattern of the hard mask 402 is then transferred, for example through a selective etch process, onto the dummy gate material thereby forming the one or more dummy gates 401. The one or more dummy gates 401 may be formed in a direction perpendicular to the first and the second raw stack of nanosheets 210 and 220.

FIGS. 2A and 2B are demonstrative illustrations of different cross-sectional views and FIG. 2C is a simplified top view of a semiconductor structure in a step of manufacturing thereof, according to one embodiment of present invention. More particularly, following the step illustrated in FIGS. 1A, 1B, and 1C, embodiments of present invention provide forming sidewall spacers 403 at sidewalls of the one or more dummy gates 401 and recessing the first and the second raw stack of nanosheets 210 and 220, using the dummy gates 401 and sidewall spacers 403 as an etch mask, to create a first stack of nanosheets 211 and a second stack of nanosheets 221. The first and the second stack of nanosheets 211 and 221 may each include a stack of alternating silicon nanosheets and sacrificial sheets. As being described below in more details, the silicon nanosheets may form channel regions of the transistors while the sacrificial sheets may be selectively removed and replaced to form a metal gate.

Additionally, embodiments of present invention provide removing and replacing the first sacrificial insulation sheet 201 with a self-aligned substrate isolation (SASI) layer 301 such as a dielectric layer of SIN, SiO₂, silicon-boron-carbonitride (SiBCN), or other suitable materials, in a deposit and selective etch process. The deposit process may be an atomic-layer deposition (ALD) process and the selective etch may be a self-aligned etch process thereby resulting in the SASI layer 301. Similarly, the second sacrificial insulation sheet 202 may be removed and replaced with a self-aligned middle isolation (SAMI) layer 302, which may be a dielectric layer of SIN, SiO₂, SiBCN, or other suitable materials as well and may be patterned together with the patterning of the first and the second stack of nanosheets 211 and 221 in a self-aligned etch process. Thereafter, inner spacers may be formed at end portions of the sacrificial sheets in the first and the second stack of nanosheets 211 and 221.

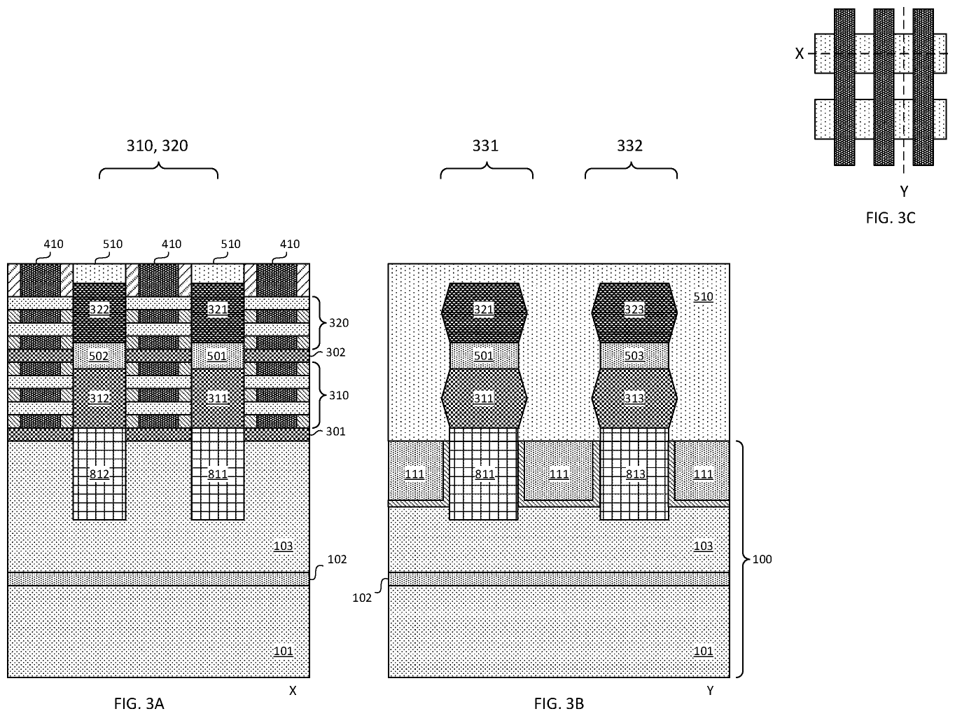

FIGS. 3A and 3B are demonstrative illustrations of different cross-sectional views and FIG. 3C is a simplified top view of a semiconductor structure in a step of manufacturing thereof, according to one embodiment of present invention. More particularly, following the step illustrated in FIGS. 2A, 2B, and 2C, embodiments of present invention provide removing or creating openings in the SASI layer 301 in areas where the first and the second raw stack of nanosheets 210 and 220 are recessed to expose the Si layer 103; recessing or removing a top portion of the exposed Si layer 103 to create one or more openings or recesses; and filling the one or more openings or recesses with a placeholder material to form one or more placeholders such as placeholders 811, 812, and 813. Suitable placeholder material may include, for example, dielectric material such as SiN, SiO₂ and may include polysilicon (Poly-Si), silicon-germanium (SiGe), or other suitable materials.

After forming the placeholders 811, 812, and 813 in the Si layer 103 of semiconductor substrate 100, S/D regions of a set of bottom transistors may be formed through an epitaxially growth process at the ends of the first stack of nanosheets 211. For example, a raw S/D region 311 may be formed for a first transistor 310 of a first stack of transistors 331, at a first end of the first stack of nanosheets 211. The raw S/D region 311 may later be patterned into a bottom S/D region, i.e., a first S/D region of the first transistor 310 of the first stack of transistors 331 as being described below in more details. In the meantime, a bottom S/D region 312 may be formed for the first transistor 310 at the second end of the first stack of nanosheets 211. In another example, a bottom S/D region 313 may be formed for a bottom transistor of a second stack of transistors 332 as is illustrated in FIG. 3B. The second stack of transistors 332 may be adjacent to or nearby the first stack of transistors 331.

Embodiments of present invention further provide forming a middle-dielectric-insulator (MDI) layer 501 on top of the raw S/D region 311 of the first transistor 310. The MDI layer 501 may be silicon-carbon (SiC) or silicon-oxycarbide (SiOC), SiBCN, and may be formed in an area adjacent to SAMI layer 302. Further for example, an MDI layer 502 may be formed on top of the bottom S/D region 312 and an MDI layer 503 may be formed on top of the bottom S/D region 313. The MDI layers 501, 502, and 503 may be formed, for example, by depositing a dielectric material layer on top of the bottom S/D regions. The dielectric material layer is then recessed to form the MDI layers 501, 502, and 503. Generally, MDI layers are formed to insulate S/D regions of top transistors from S/D regions of bottom transistors in the structure of stacked transistors 331 and 332. However, according to one embodiment of present invention, at least one of the MDI layers such as the MDI layer 501 may be removed and replaced later to form a shared S/D contact as being described below in more details.

After forming the MDI layers 501, 502 and 503, embodiments of present invention provide forming top S/D regions of a set of top transistors such as forming a top S/D region 321, i.e., a second S/D region of a second transistor 320 of the first stack of transistors 331. The top S/D region 321 may be made through an epitaxial growth process at a first end of the stack of nanosheets 221. Embodiments of present invention further provide forming a top S/D region 322 at a second end of the stack of nanosheets 221. Further for example, a top S/D region 323 may be formed for a top transistor of the second stack of transistors 332 as is illustrated in FIG. 3B. As being described above, the second stack of transistors 332 may be adjacent to or nearby the first stack of transistors 331.

After forming the top S/D regions 321, 322, and 323 for the top transistors of the first and the second stack of transistors 331 and 332, dielectric material may be deposited to form a dielectric layer 510 filling spaces between the first and the second stack of transistors 331 and 332 and covering the top S/D regions 321, 322, and 323. A chemical-mechanical-polishing (CMP) process may be applied to planarize a top surface of the dielectric layer 510 and remove the hard masks 402 until the dummy gates 401 underneath the hard masks 402 are revealed or exposed for further processing.

After being revealed, the dummy gates 401 and the sacrificial sheets between the Si nanosheets may be selectively removed, in a replacement-metal-gate (RMG) process, and replaced with a metal gate 410, thereby forming the first and the second transistor 310 and 320 of the first stack of transistors 331. Similarly, and through the same or a different RMG process, a bottom and a top transistor of the second stack of transistors 332 may be formed as well.

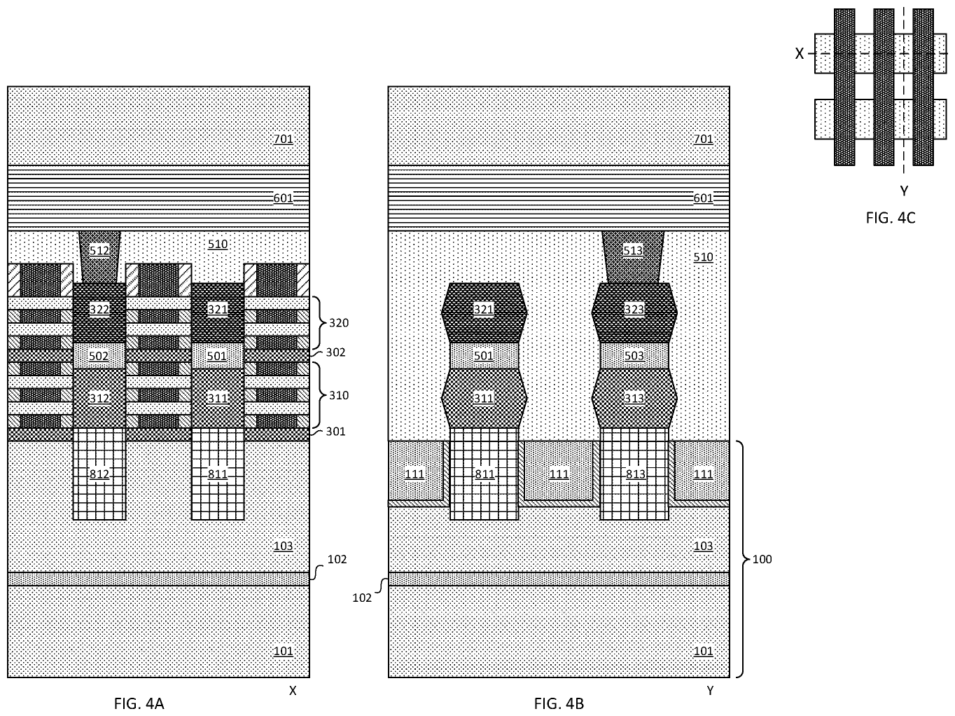

FIGS. 4A and 4B are demonstrative illustrations of different cross-sectional views and FIG. 4C is a simplified top view of a semiconductor structure in a step of manufacturing thereof, according to one embodiment of present invention. More particularly, following the step illustrated in FIGS. 3A, 3B, and 3C, embodiments of present invention provide depositing additional dielectric material, optionally and if needed, to increase the height of the dielectric layer 510 and forming one or more frontside S/D contacts in the dielectric layer 510 to contact S/D regions of the transistors at the top. For example, a first frontside S/D contact 512 may be formed to be in contact with the top S/D region 322 of the second transistor 320, and a second frontside S/D contact 513 may be formed to be in contact with the top S/D region 323 of the top transistor of the second stack of transistors 332.

Embodiments of present invention further provide forming a back-end-of-line (BEOL) structure 601 on top of the dielectric layer 510. The BEOL structure 601 provide signal powering and routing functionalities to the transistors through, for example, the one or more frontside S/D contacts and/or contacts to the gates of the transistors. A carrier wafer 701 is then bonded onto the BEOL structure 601 such that the semiconductor structure 10 may be flipped up-side-down for further processing from the backside.

Hereinafter, the description will be provided with the understanding that the processing is performed from the backside of the structure, although for the ease of illustration, figures and/or drawings of the semiconductor structure will still be provided in an upside-up fashion or orientation.

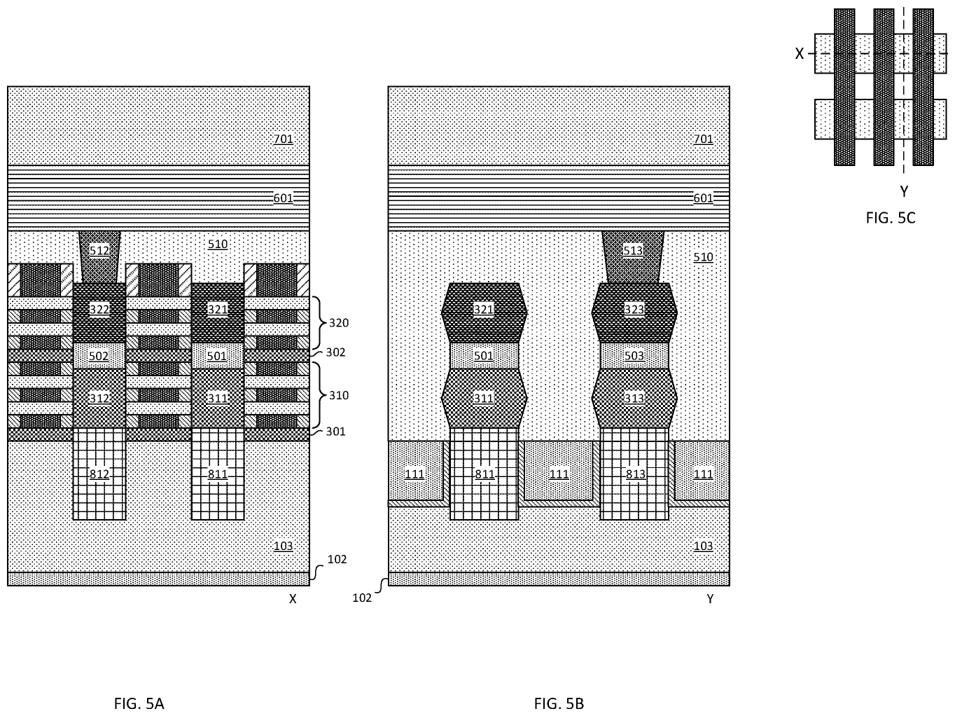

FIGS. 5A and 5B are demonstrative illustrations of different cross-sectional views and FIG. 5C is a simplified top view of a semiconductor structure in a step of manufacturing thereof, according to one embodiment of present invention. More particularly, following the step illustrated in FIGS. 4A, 4B, and 4C, embodiments of present invention provide removing the silicon substrate 101 in a grinding process, a CMP process, and/or other selective etch process. The removal of the silicon substrate 101 may stop at and expose the etch-stop layer 102.

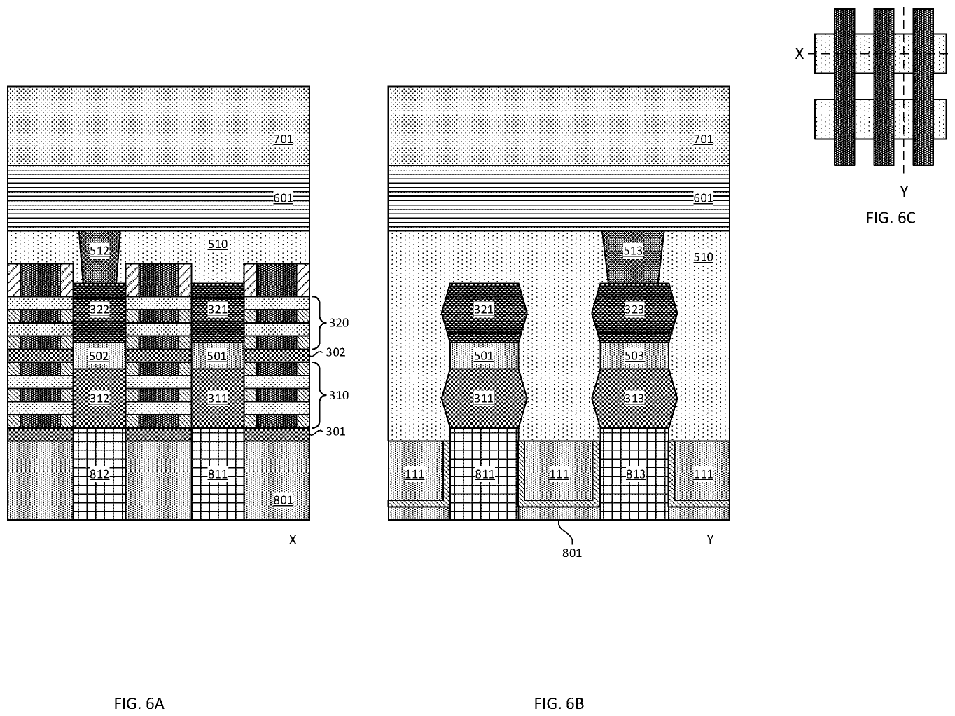

FIGS. 6A and 6B are demonstrative illustrations of different cross-sectional views and FIG. 6C is a simplified top view of a semiconductor structure in a step of manufacturing thereof, according to one embodiment of present invention. More particularly, following the step illustrated in FIGS. 5A, 5B, and 5C, embodiments of present invention provide removing the etch-stop layer 102 to expose the underneath Si layer 103. Subsequently, the Si layer 103 may be selectively removed and a dielectric material may be deposited to cover the exposed one or more placeholders 811, 812, and 813 and STI's 111. Next, a CMP process may be applied to planarize the deposited dielectric material thereby forming a dielectric layer 801 and revealing the one or more placeholders 811, 812, and 813.

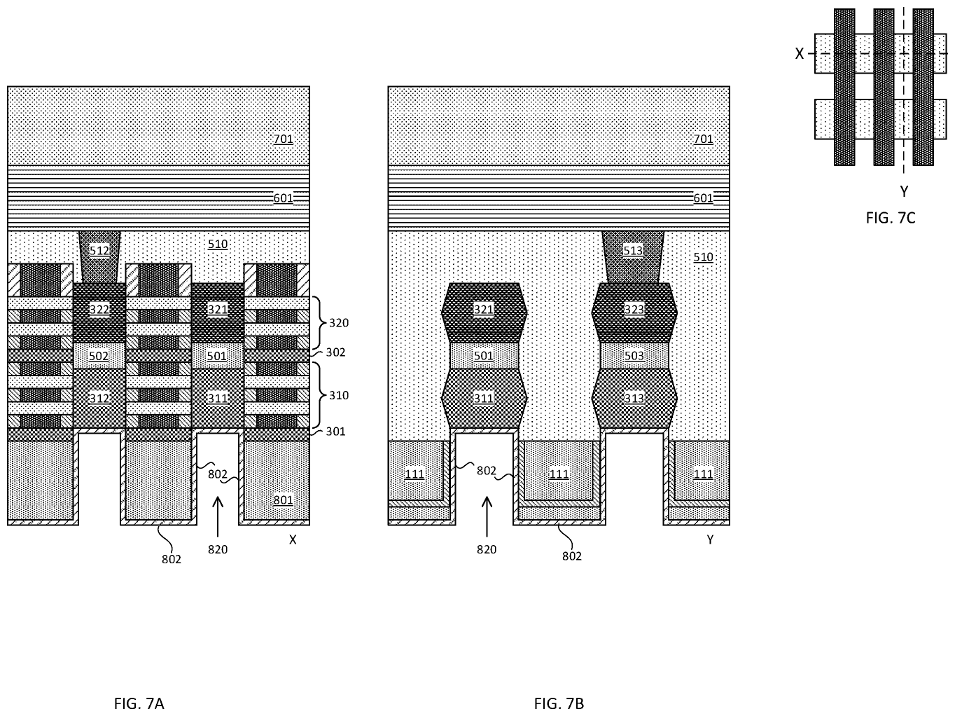

FIGS. 7A and 7B are demonstrative illustrations of different cross-sectional views and FIG. 7C is a simplified top view of a semiconductor structure in a step of manufacturing thereof, according to one embodiment of present invention. More particularly, following the step illustrated in FIGS. 6A, 6B, and 6C, embodiments of present invention provide removing the revealed or exposed one or more placeholders 811, 812, and 813. For example, the placeholder 811 may be removed through a selective etch process to create a first opening 820 in the dielectric layer 801. By the nature that the raw S/D region 311 is epitaxially formed from the placeholder 811, the first opening 820 may be self-aligned to the raw S/D region 311 of the first transistor 310.

According to one embodiment of present invention, a spacer layer 802 may be formed through deposition onto sidewalls of the first opening 820 thereby reducing a width of the first opening 820. For example, in one embodiment, the spacer layer 802 may be a conformal dielectric liner having a width ranging from about 5 nm to about 7 nm, and may be made of, for example, SiC, SiOC, SiN or other suitable materials.

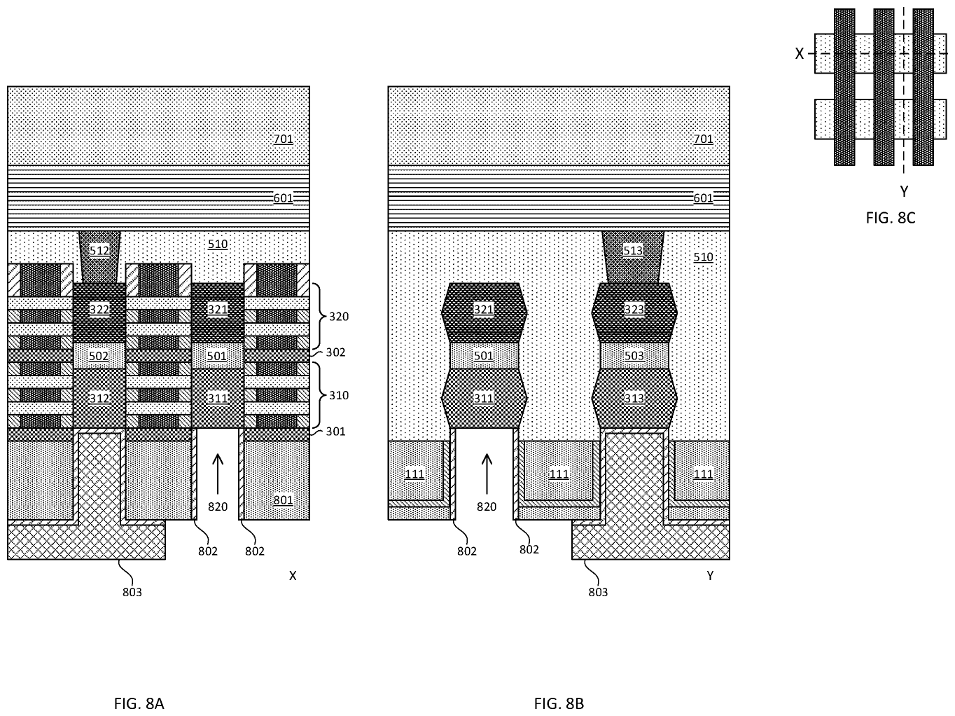

FIGS. 8A and 8B are demonstrative illustrations of different cross-sectional views and FIG. 8C is a simplified top view of a semiconductor structure in a step of manufacturing thereof, according to one embodiment of present invention. More particularly, following the step illustrated in FIGS. 7A, 7B, and 7C, embodiments of present invention provide forming a dielectric layer such as an organic planarization (OPL) layer 803 that exposes the first opening 820 while covering rest of the structure such as covering openings underneath the bottom S/D regions 312 and 313. In one embodiment, the OPL layer 803 may be formed through, for example, first depositing a blanket OPL layer on top of the spacer layer 802 and the one or more openings. Next, a hard mask may be formed, through a lithographic patterning and etching process, to cover a portion of the blanket OPL layer. Portions of the blanket OPL layer that are not covered by the hard mask may be etched away in a selective and directional etch process. In the process of forming the OPL layer 803, the horizontal portions of the spacer layer 802 that are exposed by the removal of portions of the blanket OPL layer may also be removed. The removal of portions of the spacer layer 802 leaves only vertical portions of the spacer layer 802 at sidewalls of the first opening 820. The spacer layer 802 at the sidewalls cover an edge portion of the raw S/D region 311 while a central portion of the raw S/D region 311 may be exposed.

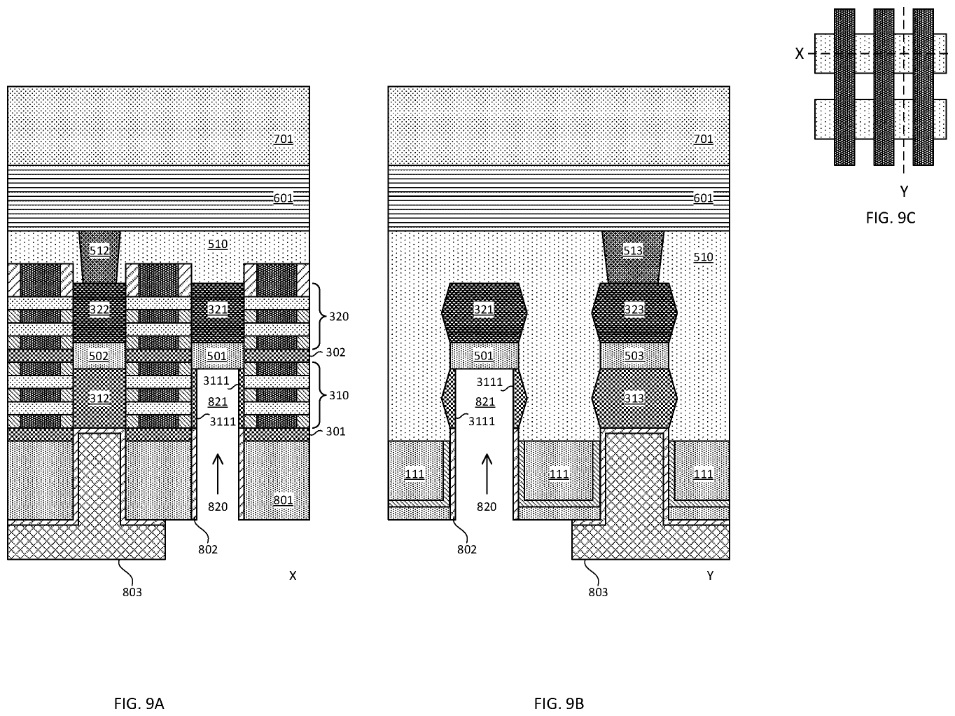

FIGS. 9A and 9B are demonstrative illustrations of different cross-sectional views and FIG. 9C is a simplified top view of a semiconductor structure in a step of manufacturing thereof, according to one embodiment of present invention. More particularly, following the step illustrated in FIGS. 8A, 8B, and 8C, embodiments of present invention provide selectively, and directionally, etching the exposed central portion of the raw S/D region 311 until the underneath MDI layer 501 is exposed. The removal of the central portion of the raw S/D region 311 may create a second opening 821 and leave the rest of the raw S/D region 311 to form a first S/D region 3111. The first S/D region 3111, i.e., a bottom S/D region of the first transistor 310 may surround the second opening 821. As is illustrated in FIGS. 9A and 9B, the first S/D region 3111 may have a top surface that is in direct contact with the MDI layer 501 and may have a bottom surface that is covered by and in direct contact with the vertical portions of the spacer layer 802. In other words, the spacer layer 802 is directly on top of a bottom surface of the first S/D region 3111.

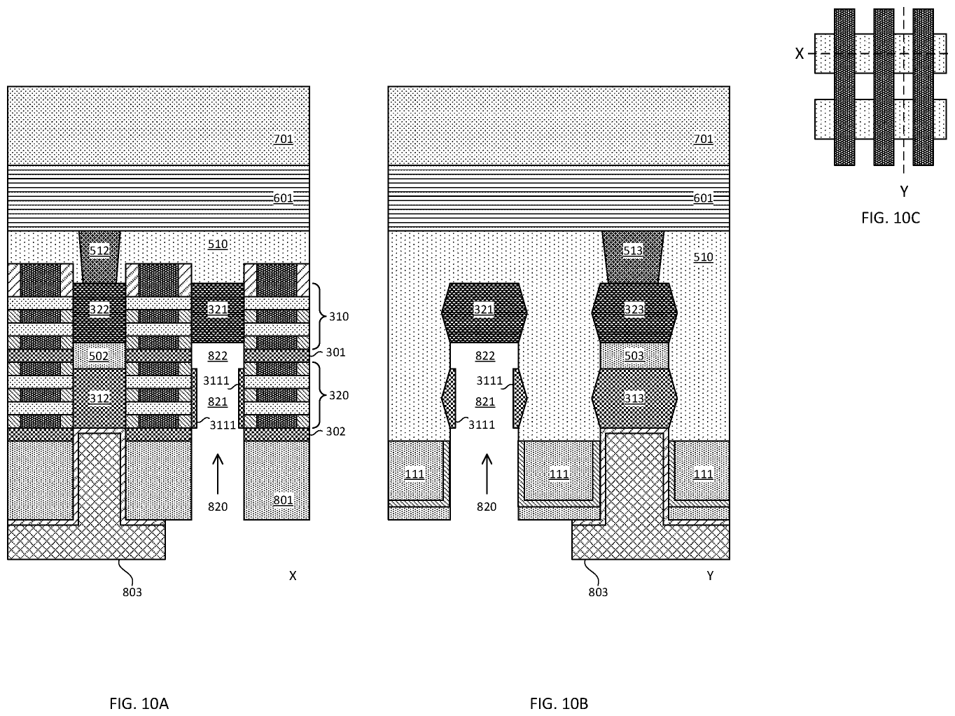

FIGS. 10A and 10B are demonstrative illustrations of different cross-sectional views and FIG. 10C is a simplified top view of a semiconductor structure in a step of manufacturing thereof, according to one embodiment of present invention. More particularly, following the step illustrated in FIGS. 9A, 9B, and 9C, embodiments of present invention provide continuing to etch the exposed MDI layer 501, through the second opening 821, in an isotropic etch process. The isotropic etch process may remove the MDI layer 501 to create a third opening 822. The third opening 822 exposes a bottom surface of the second S/D region 321 of the second transistor 320 and may as well expose the top surface of the first S/D region 3111 that were previously in contact with the MDI layer 501.

Embodiments of present invention may also remove the spacer layer 802 at the sidewalls of the first opening 820 thereby exposing the bottom surface of the first S/D region 3111 that were previously covered by and in contact with the spacer layer 802.

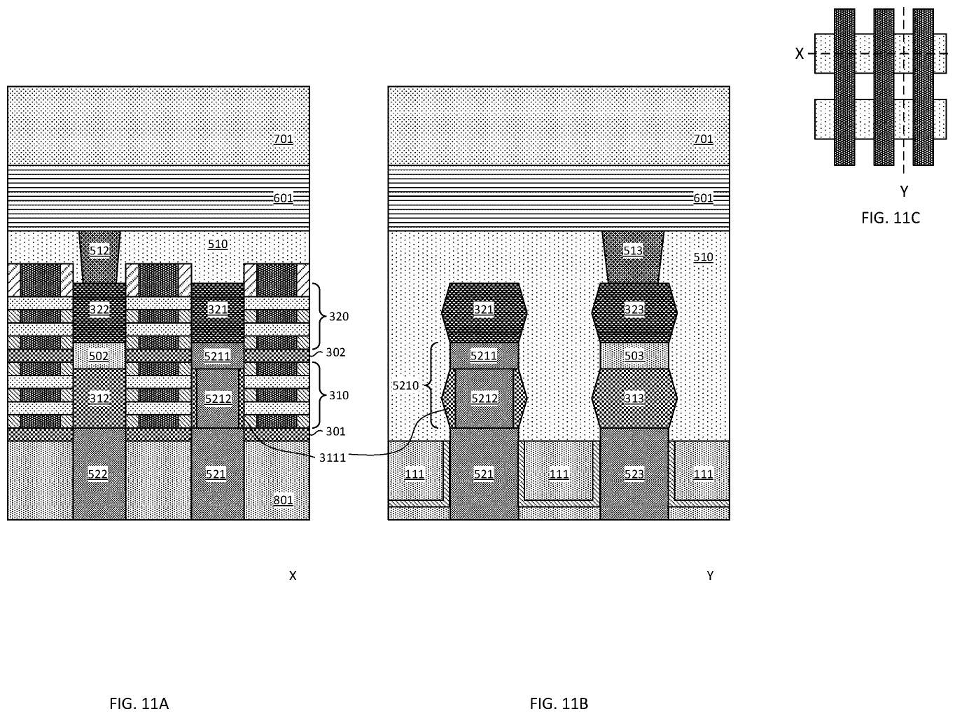

FIGS. 11A and 11B are demonstrative illustrations of different cross-sectional views and FIG. 11C is a simplified top view of a semiconductor structure in a step of manufacturing thereof, according to one embodiment of present invention. More particularly, following the step illustrated in FIGS. 10A, 10B, and 10C, embodiments of present invention provide removing the OPL layer 803 and the spacer layer 802 exposed by the removal of the OPL layer 803. The removal of the OPL layer 803 and the spacer layer 802 exposes the other bottom S/D regions such as the bottom S/D regions 312 and 313 for forming backside S/D contacts.

Next, embodiments of present invention provide filling the third opening 822 with a conductive material such as, for example, copper (Cu), tungsten (W), cobalt (Co), ruthenium (Ru), or other suitable contact materials to form a first portion 5211 of a shared S/D contact 5210. The conductive material may be filled in the third opening 822 using, for example, a CVD process, a plating process, or other suitable processes. A bottom surface of the first portion 5211 of the shared S/D contact 5210 may be in contact with the top surface of the first S/D region 3111.

The same conductive material, or a different conductive material, may be used to further fill the second opening 821, following the filling of the third opening 822, to form a second portion 5212 of the shared S/D contact 5210. The second portion 5212 of the shared S/D contact 5210 is wrapped around by the first S/D region 3111. Here, the first portion 5211 and the second portion 5212 together form the shared S/D contact 5210.

As is demonstratively illustrated in FIGS. 11A and 11B, the first portion 5211 of the shared S/D contact 5210 may have a first horizontal cross-section, and the second portion 5212 of the shared S/D contact 5210 may have a second horizontal cross-section. Since the second portion 5212 of the shared S/D contact 5210 is wrapped around by the first S/D region 3111, the first horizontal cross-section may be larger than the second horizontal cross-section.

Upon forming the shared S/D contact 5210, i.e., upon forming the second portion 5212 of the shared S/D contact 5210, embodiments of present invention provide continuing to fill the first opening 820 with the conductive material, or a different conductive material, to form a backside S/D contact 521. The backside S/D contact 521 may be self-aligned with the first S/D region 3111 and the bottom surface of the first S/D region 3111 is in direct contact with the backside S/D contact 521. Here, it is noted that first portion 5211, the second portion 5212, and the backside S/D contact 521 may together form a single backside S/D contact structure, particularly when a same conductive material is used to form the structure.

The same, or different, conductive material may be used to fill openings underneath other bottom S/D regions to form backside S/D contacts such as, for example, backside S/D contacts 522 and 523.

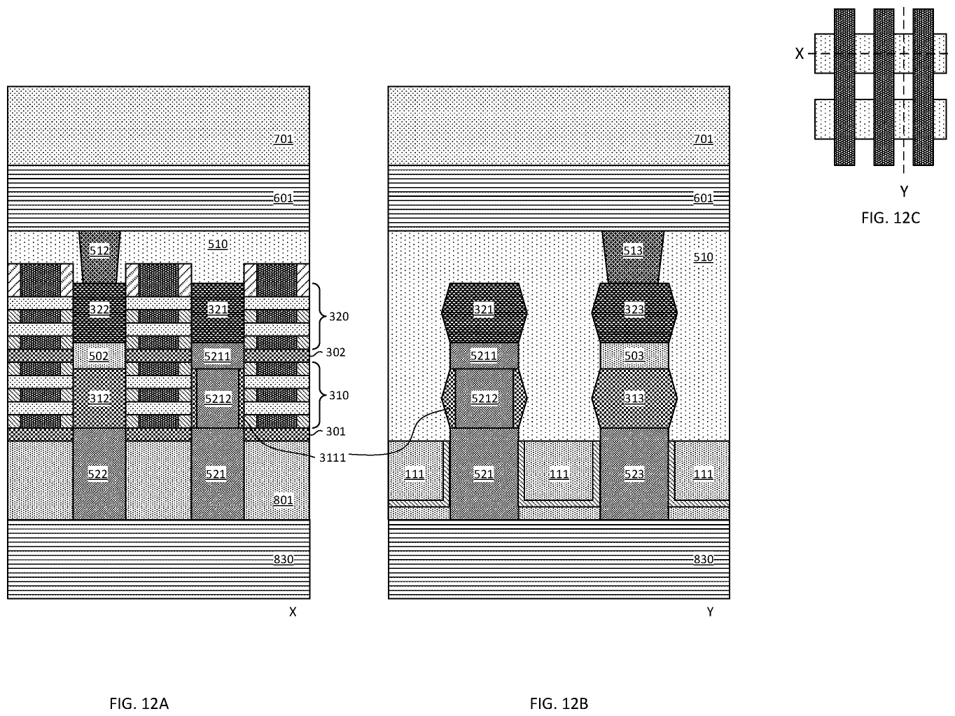

FIGS. 12A and 12B are demonstrative illustrations of different cross-sectional views and FIG. 12C is a simplified top view of a semiconductor structure in a step of manufacturing thereof, according to one embodiment of present invention. More particularly, following the step illustrated in FIGS. 11A, 11B, and 11C, embodiments of present invention provide forming a backside interconnect structure 830 on top of the dielectric layer 801 and on top of and in contact with the backside S/D contacts 821, 822, and 823. The backside interconnect structure 830 may provide signal powering and routing functionalities to the first and the second stack of transistors 331 and 332.

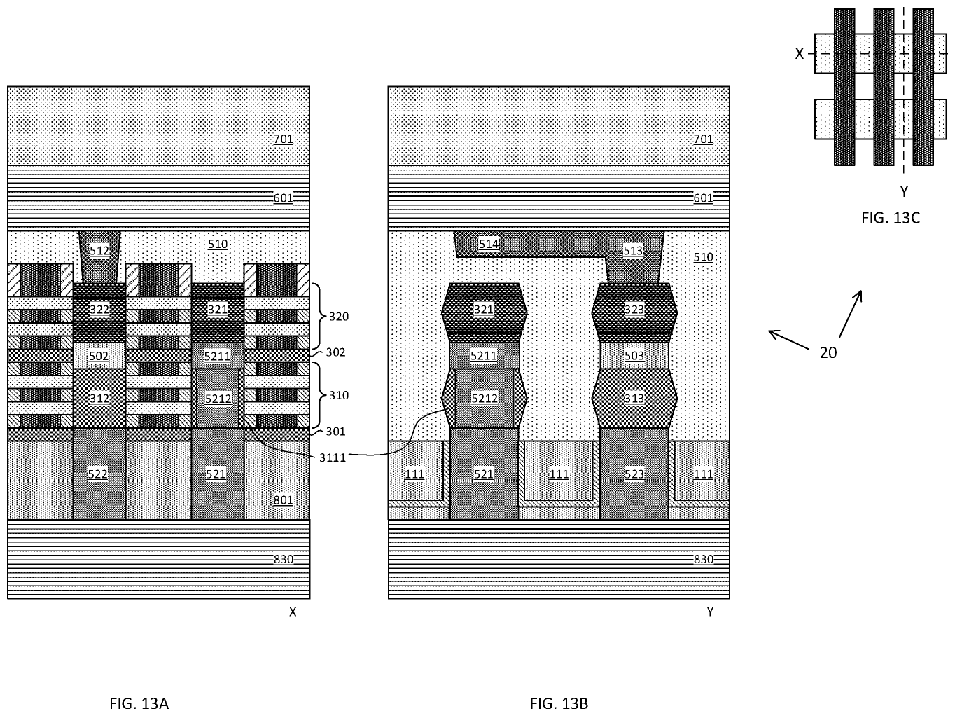

FIGS. 13A and 13B are demonstrative illustrations of cross-sectional views and FIG. 13C is a simplified top view of a semiconductor structure according to another embodiment of present invention. More particularly, embodiments of present invention provide a semiconductor structure 20 that is substantially same in structure as the semiconductor structure 10 as being described above. Moreover, the semiconductor structure 20 may include a contact metal 514 formed directly above but insulated from the second S/D region 321 of the second transistor 320. The contact metal 514 may extend from a frontside S/D contact 513 that is in contact with a top S/D region of a top transistor of a nearby stack of transistors such as the top S/D region of the top transistor of the second stack of transistors 332.

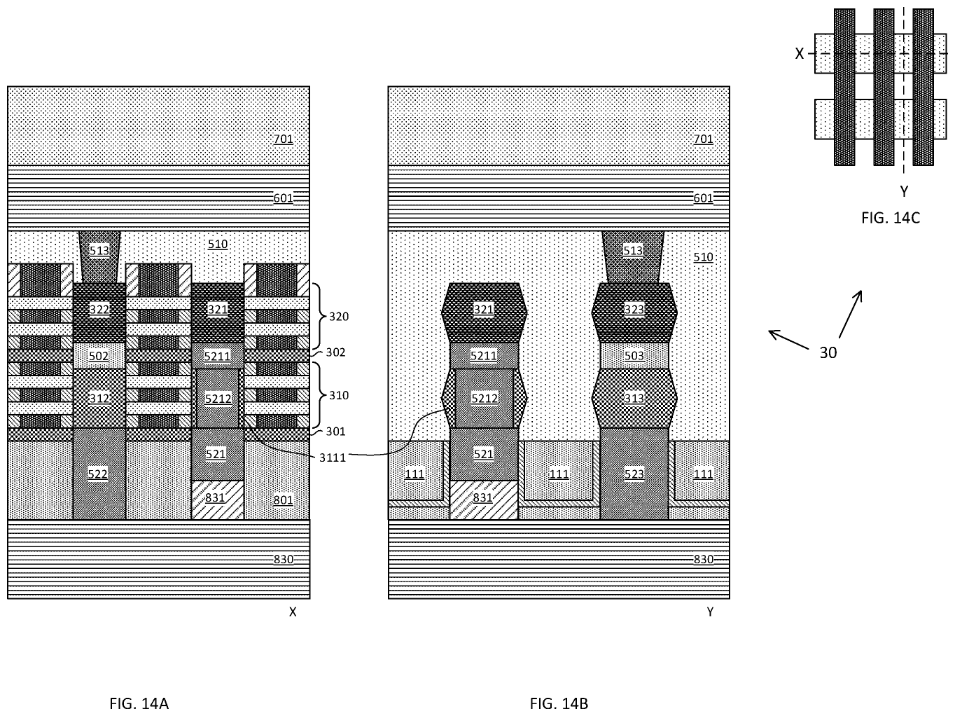

FIGS. 14A and 14B are demonstrative illustrations of cross-sectional views and FIG. 14C is a simplified top view of a semiconductor structure according to yet another embodiment of present invention. More particularly, embodiments of present invention provide a semiconductor structure 30 that is substantially same in structure as the semiconductor structure 10 as being described above. Moreover, the backside S/D contact 521 in the semiconductor structure 30 may be recessed, relative to the surrounding dielectric layer 801, and may be covered by a dielectric capping layer 831. The dielectric capping layer 831 insulates the backside S/D contact and the shared S/D contact 5210 from the backside interconnect structure 830. In other words, in the semiconductor structure 30, the shared S/D contact 5210 and the backside S/D contact 521 provide an internal connection between the first S/D region 3111 and the second S/D region 321.

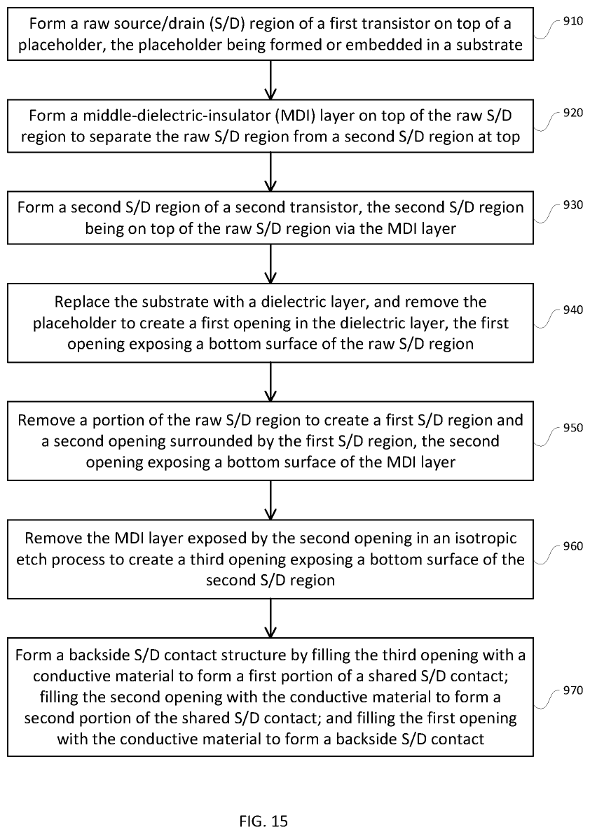

FIG. 15 is a demonstrative illustration of a flow-chart of a method of manufacturing a semiconductor structure according to embodiments of present invention. The method includes (910) forming a raw source/drain (S/D) region of a first transistor on top of a placeholder, the placeholder being formed or embedded in a substrate; (920) forming a middle-dielectric-insulator (MDI) layer on top of the raw S/D region to separate the raw S/D region from a second S/D region at top; (930) forming a second S/D region of a second transistor, the second S/D region being on top of the raw S/D region via the MDI layer; (940) replacing the substrate with a dielectric layer, and removing the placeholder to create a first opening in the dielectric layer, the first opening exposing a bottom surface of the raw S/D region; (950) removing a portion of the raw S/D region to create a first S/D region and a second opening surrounded by the first S/D region, the second opening exposing a bottom surface of the MDI layer; (960) removing the MDI layer exposed by the second opening in an isotropic etch process to create a third opening exposing a bottom surface of the second S/D region; and (970) forming a backside S/D contact structure by filling the third opening with a conductive material to form a first portion of a shared S/D contact; filling the second opening with the conductive material to form a second portion of the shared S/D contact; and filling the first opening with the conductive material to form a backside S/D contact.

Various examples may possibly be described by one or more of the following features in the following numbered clauses:
Clause 1: A semiconductor structure comprising a first transistor having a first source/drain (S/D) region; a second transistor having a second S/D region, the second S/D region being on top of the first S/D region; and a shared S/D contact, the shared S/D contact having a first portion being in direct contact with a bottom surface of the second S/D region of the second transistor and a second portion being wrapped around by the first S/D region of the first transistor.
Clause 2: The semiconductor structure of clause 1, further comprising a backside S/D contact in contact with a bottom surface of the second portion of the shared S/D contact.
Clause 3: The semiconductor structure of clause 2, wherein the first portion of the shared S/D contact has a first horizontal cross-section, and the second portion of the shared S/D contact has a second horizontal cross-section; the first horizontal cross-section being larger than the second horizontal cross-section.
Clause 4: The semiconductor structure of clause 3, wherein the backside S/D contact has a third horizontal cross-section, the third horizontal cross-section being larger than the second horizontal cross-section.
Clause 5: The semiconductor structure of clause 2, wherein the first portion of the shared S/D contact is in direct contact with a top surface of the first S/D region that surrounds the second portion of the shared S/D contact.
Clause 6: The semiconductor structure of clause 2, wherein the backside S/D contact is in direct contact with a bottom surface of the first S/D region that surrounds the second portion of the shared S/D contact.
Clause 7: The semiconductor structure of clause 2, further comprising a backside interconnect structure underneath the first transistor, wherein the second portion of the shared S/D contact is insulated from the backside interconnect structure by a dielectric capping layer.
Clause 8: The semiconductor structure of clause 1, further comprising a contact metal directly above and insulated from the second S/D region of the second transistor, the contact metal extending from a frontside S/D contact of a nearby transistor.
Clause 9: A semiconductor structure comprising: a first stack of transistors having a first source/drain (S/D) region and a second S/D region, the second S/D region being on top of the first S/D region; a second stack of transistors having a third S/D region and a fourth S/D region, the fourth S/D region being on top of the third S/D region, the second stack of transistors being adjacent to the first stack of transistors; and a shared S/D contact, the shared S/D contact having a first portion being in direct contact with a bottom surface of the second S/D region and a second portion being wrapped around by the first S/D region.
Clause 10: The semiconductor structure of clause 9, wherein the third S/D region is insulated from the fourth S/D region of the second stack of transistors by a middle-dielectric-insulator (MDI) layer, the MDI layer has a thickness that is substantially same as a thickness of the first portion of the shared S/D contact.
Clause 11: The semiconductor structure of clause 9, further comprising a backside interconnect structure underneath the first and the second stack of transistors, wherein the second portion of the shared S/D contact is insulated from the backside interconnect structure by a dielectric capping layer.
Clause 12: The semiconductor structure of clause 9, further comprising a backside interconnect structure, underneath the first and the second stack of transistors, and a backside S/D contact, wherein the second portion of the shared S/D contact is conductively connected to the backside interconnect structure by the backside S/D contact.
Clause 13: The semiconductor structure of clause 12, wherein the first portion of the shared S/D contact is in direct contact with a top surface of the first S/D region that surrounds the second portion of the shared S/D contact.
Clause 14: The semiconductor structure of clause 12, wherein the backside S/D contact is in direct contact with a bottom surface of the first S/D region that surrounds the second portion of the shared S/D contact.
Clause 15: The semiconductor structure of clause 9, further comprising a contact metal directly above and insulated from the second S/D region, the contact metal extending from a frontside S/D contact of the fourth S/D region of the second stack of transistors.
Clause 16: A method of forming a semiconductor structure comprising forming a raw source/drain (S/D) region of a first transistor on top of a placeholder, the placeholder being formed in a substrate; forming a middle-dielectric-insulator (MDI) layer on top of the raw S/D region; forming a second S/D region of a second transistor on top of, via the MDI layer, the raw S/D region; replacing the substrate with a dielectric layer and removing the placeholder to create a first opening in the dielectric layer, the first opening exposing a bottom surface of the raw S/D region; removing a portion of the raw S/D region to create a first S/D region and a second opening surrounded by the first S/D region, the second opening exposing a bottom surface of the MDI layer; removing the MDI layer exposed by the second opening to create a third opening; and forming a shared S/D contact by filling the third opening with a conductive material to form a first portion of the shared S/D contact and filling the second opening with the conductive material to form a second portion of the shared S/D contact.
Clause 17: The method of clause 16, wherein removing a portion of the raw S/D region comprises forming a spacer layer at sidewalls of the first opening, the spacer layer being directly on top of a bottom surface of the first S/D region and exposing the portion of the raw S/D region, and removing the portion of the raw S/D region in a selective etch process.
Clause 18: The method of clause 17, further comprising removing the spacer layer to expose the bottom surface of the first S/D region; and depositing the conductive material in the first opening to form a backside S/D contact, the backside S/D contact in direct contact with a bottom surface of the second portion of the shared S/D contact and with the bottom surface of the first S/D region.
Clause 19: The method of clause 18, further comprising covering the backside S/D contact with a dielectric capping layer; and forming a backside interconnect structure, the backside interconnect structure being insulated from the shared S/D region by the dielectric capping layer.
Clause 20: The method of clause 16, wherein removing the MDI layer comprises etching the MDI layer in an isotropic etch process, through the second opening, to expose a bottom surface of the second S/D region and a top surface of the first S/D region.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first transistor having a first source/drain (S/D) region;
a second transistor having a second S/D region, the second S/D region being on top of the first S/D region; and
a shared S/D contact, the shared S/D contact having a first portion being in direct contact with a bottom surface of the second S/D region of the second transistor and a second portion being wrapped around by the first S/D region of the first transistor.

2. The semiconductor structure of claim 1, further comprising a backside S/D contact in contact with a bottom surface of the second portion of the shared S/D contact.

3. The semiconductor structure of claim 2, wherein the first portion of the shared S/D contact has a first horizontal cross-section, and the second portion of the shared S/D contact has a second horizontal cross-section; the first horizontal cross-section being larger than the second horizontal cross-section.

4. The semiconductor structure of claim 3, wherein the backside S/D contact has a third horizontal cross-section, the third horizontal cross-section being larger than the second horizontal cross-section.

5. The semiconductor structure of claim 2, wherein the first portion of the shared S/D contact is in direct contact with a top surface of the first S/D region that surrounds the second portion of the shared S/D contact.

6. The semiconductor structure of claim 2, wherein the backside S/D contact is in direct contact with a bottom surface of the first S/D region that surrounds the second portion of the shared S/D contact.

7. The semiconductor structure of claim 2, further comprising a backside interconnect structure underneath the first transistor, wherein the second portion of the shared S/D contact is insulated from the backside interconnect structure by a dielectric capping layer.

8. The semiconductor structure of claim 1, further comprising a contact metal directly above and insulated from the second S/D region of the second transistor, the contact metal extending from a frontside S/D contact of a nearby transistor.

9. A semiconductor structure comprising:
a first stack of transistors having a first source/drain (S/D) region and a second S/D region, the second S/D region being on top of the first S/D region;
a second stack of transistors having a third S/D region and a fourth S/D region, the fourth S/D region being on top of the third S/D region, the second stack of transistors being adjacent to the first stack of transistors; and
a shared S/D contact, the shared S/D contact having a first portion being in direct contact with a bottom surface of the second S/D region and a second portion being wrapped around by the first S/D region.

10. The semiconductor structure of claim 9, wherein the third S/D region is insulated from the fourth S/D region of the second stack of transistors by a middle-dielectric-insulator (MDI) layer, a thickness of the MDI layer is substantially same as a thickness of the first portion of the shared S/D contact.

11. The semiconductor structure of claim 9, further comprising a backside interconnect structure underneath the first and the second stack of transistors, wherein the second portion of the shared S/D contact is insulated from the backside interconnect structure by a dielectric capping layer.

12. The semiconductor structure of claim 9, further comprising a backside interconnect structure, underneath the first and the second stack of transistors, and a backside S/D contact, wherein the second portion of the shared S/D contact is conductively connected to the backside interconnect structure by the backside S/D contact.

13. The semiconductor structure of claim 12, wherein the first portion of the shared S/D contact is in direct contact with a top surface of the first S/D region that surrounds the second portion of the shared S/D contact.

14. The semiconductor structure of claim 12, wherein the backside S/D contact is in direct contact with a bottom surface of the first S/D region that surrounds the second portion of the shared S/D contact.

15. The semiconductor structure of claim 9, further comprising a contact metal directly above and insulated from the second S/D region, the contact metal extending from a frontside S/D contact of the fourth S/D region of the second stack of transistors.

16. A method of forming a semiconductor structure comprising:
forming a raw source/drain (S/D) region of a first transistor on top of a placeholder, the placeholder being formed in a substrate;
forming a middle-dielectric-insulator (MDI) layer on top of the raw S/D region;
forming a second S/D region of a second transistor on top of, via the MDI layer, the raw S/D region;
replacing the substrate with a dielectric layer and removing the placeholder to create a first opening in the dielectric layer, the first opening exposing a bottom surface of the raw S/D region;
removing a portion of the raw S/D region to create a first S/D region and a second opening surrounded by the first S/D region, the second opening exposing a bottom surface of the MDI layer;
removing the MDI layer exposed by the second opening to create a third opening; and
forming a shared S/D contact by filling the third opening with a conductive material to form a first portion of the shared S/D contact and filling the second opening with the conductive material to form a second portion of the shared S/D contact.

17. The method of claim 16, wherein removing a portion of the raw S/D region comprises forming a spacer layer at sidewalls of the first opening, the spacer layer being directly on top of a bottom surface of the first S/D region and exposing the portion of the raw S/D region, and removing the portion of the raw S/D region in a selective etch process.

18. The method of claim 17, further comprising:
removing the spacer layer to expose the bottom surface of the first S/D region; and
depositing the conductive material in the first opening to form a backside S/D contact, the backside S/D contact in direct contact with a bottom surface of the second portion of the shared S/D contact and with the bottom surface of the first S/D region.

19. The method of claim 18, further comprising:
covering the backside S/D contact with a dielectric capping layer; and
forming a backside interconnect structure, the backside interconnect structure being insulated from the shared S/D region by the dielectric capping layer.

20. The method of claim 16, wherein removing the MDI layer comprises etching the MDI layer in an isotropic etch process, through the second opening, to expose a bottom surface of the second S/D region and a top surface of the first S/D region.
